(19) United States
(12) Patent Application Publication
(10) Pub. No.: US 2008/0192421 A1
(43) Pub. Date: Aug. 14, 2008

(54) Bag computer multi function hinge

(76) Inventor: Charles A. Daley, Rawai (TH)

Correspondence Address: Charles A. Daley III, P.O. Box 184, Karon PO, T. Karon, A. Muang, 83100, omitted

(21) Appl. No.: 12/079,753

(22) Filed: Mar. 31, 2008

Related U.S. Application Data
(60) Provisional application No. 60/998,809, filed on Oct. 15, 2007.

(51) Int. Cl. H05K 5/00

(52) U.S. Cl. 361/681

(57) ABSTRACT

Disclosed is a multi function hinge for bag computers which may include one or more of five functions to improve the operation of a bag computer. The functions include 1) a hinge which can alternate between holding the display at any angle and allowing the display to pivot freely without restraint, 2) speakers mounted to the hinge so that sound can be heard outside the bag without sound openings in the bag, 3) a heat dissipation outlet to allow cooling of an inside mounted computer, 4) an infrared antenna mounted on the hinge for communicating with other bag computer components or outside receivers/sources, 5) a hinge capability of pivoting 180 degrees for viewing from behind the bag.

### CROSS-REFERENCE TO RELATED APPLICATIONS

This application claims the filing benefit under 35 U.S.C. §119(e) of U.S. Provisional Application No. 60/998,809, filed on Oct. 15, 2007, the entire teachings of which are incorporated herein by reference.

Related to patent application Ser. No. 11/799,011, filed May 1, 2007

Related to patent application Ser. No. 11/796,920, filed May 1, 2007

### TECHNICAL FIELD

The present invention relates to a computer designed to be mounted on a bag front for mobile use.

### BACKGROUND OF THE INVENTION

Bag computers are a combination of a bag, computer and display such that the bag wearer/operator can pivot the display into his line of sight for use. Manual controls are also included on the outside of the bag so that the operator can use the computer on short notice in any situation without unloading it or setting it up for use.

Because it is used vertically and in the mobile environment, it may be used and physically improved in ways not needed for other portable computers such as lap tops or handhelds.

For example, a bag computer user might want the option to have the display panel hold its position for viewing without using the hands or have the display panel swing freely so it may automatically fall flat against the bag front and out of the way when not held so as to not interfere with other tasks the operator might have.

Because the hinge might be the only part of the computer body on the outside of the bag, it is the most reasonable venue for mounting speakers, a heat dissipation duct outlet or a line of sight infrared antenna.

Because of the stabilizing effect of the bag and the bag strap, the bag may be “balanced” in the lap while seated, with or without using the hands, to improve viewing qualities if the hinge is constructed to pivot 180 degrees from its stored position against the bag front.

These hinge improvements apply to bag computers which were described in U.S. application Ser. Nos. 11/796,920, 11/799,011, 11/163,763 and 11/001,428.

### BRIEF DESCRIPTION OF THE INVENTION

The bag computer multi function hinge is meant to improve the operation of bag computers. Bag computers include a display pivotally mounted to the outside front of a matching bag. The hinge for the display thus may become a venue for improving the bag computer's quality.

The hinge may be configured to allow the display to either move with restrain or locking so that the operators may view the display without holding it.

Alternatively, the operator may want the display to move without restrains so that it may fall flat against the bag front and out of the way when not held. The restrain may be caused by friction between the display hinge members and the bag hinge members or by friction between a brake on one hinge member and the axle fixed to the other hinge member. A switch, button or dial allows the operator to quickly make the change.

The hinge may be a venue for mounting speakers. One or more speakers may be mounted within an inside mounted computer body with a tunnel and opening leading to the outside surface of the hinge. Instead, speakers may be mounted directly to the hinge.

The hinge may be a venue for the outlet of a heat dissipation duct leading from inside the computer body. The duct may be combined with a speaker tunnel to form a single outlet.

The hinge may be a venue for an infrared antenna. Because of the hinge's location outside the bag, a line of sight antenna connected directly to the computer body may be used.

The hinge may be configured to swing 180 degrees so that the display is facing an operator in back of the bag. In the sitting position with the bag in the operator's lap and the bag's strap support the upper part of the bag, the operator can view the display more easily.

### BRIEF DESCRIPTION OF THE SEVERAL VIEWS OF THE DRAWINGS

FIG. 1 This is a bag computer with the hinge attached to the bag front and separate computer inside.

FIG. 2A This is a bag computer with the hinge attached to the bag front, separate computer inside and the display removed

FIG. 2B This shows the display with one possible attachments means to match the bag.

FIG. 3 This is a computer with body and display hinged together and computer to bag coupling.

FIG. 4 This is a computer with body and display hinged together made to mounting in an outside holster.

FIG. 5 This is a computer with body and display hinged together with attachments to match a docking port of the bag's outside front wall.

FIG. 6 This is a computer with body and display hinged together with a coupling to match the top wall of the bag.

FIG. 7 This is a computer with body and display hinged together with the display facing the body when closed. Included is a computer to bag coupling and attachments to match the bag.

FIG. 8 This is a computer with body and display hinged together with the display facing the body when closed. Included are attachments to match the bag.

FIG. 9 Shown are views of the multi function hinge with the friction disengagements function (engaged and disengaged).

FIG. 10 This is a magnification of the hinge disengagement mechanism with friction between the display and body half hinges.

FIG. 11 Shown are views of the multi function hinge with the friction disengagements function (engaged and disengaged).

FIG. 12 This is a magnification of the hinge disengagement mechanism with friction between the body half hinge and axle.

FIG. 13 This is a computer for bag mounting with body and display hinged together and speaker in the hinge.

FIG. 14A This is the multi function hinge with a speaker in the hinge using a tunnel from a speaker mounted inside of the computer body.

FIG. 14B This is a magnified cross section of the hinge speaker using a tunnel from a speaker inside the computer body.

FIG. 15A This is the multi function hinge with a speaker in the hinge using a speaker mounted directly to the hinge extension of the computer body.

FIG. 15B This is a magnified cross section of the hinge speaker mounted directly to the hinge extension of the computer body.

FIG. 16 This is a bag computer with the hinge attached to the bag front, separate computer inside and the display removed. A speaker is mounted facing up on the display half hinge.

FIG. 17A This is a cross section of a bag computer, with bag, using a hinge attached to the bag front and separate computer inside (display not shown). The speaker, inside the computer body, has a sound tunnel which matched a sound tunnel is the bags computer to bag coupling.

FIG. 17B This is a magnified view of a cross section of a bag computer using a hinge attached to the bag front and separate computer inside (display not shown). The speaker, inside the computer body, has a sound tunnel which matched a sound tunnel is the bags computer to bag coupling.

FIG. 18A This is a cross section of a bag computer, with bag, using a hinge attached to the bag front (inside computer and display not shown). It shows the computer to bag coupling with opening and sound tunnel that match the computer.

FIG. 18B This is a magnified view of a cross section of a bag computer using a hinge attached to the bag front (inside computer and display not shown). It shows the computer to bag coupling with opening and sound tunnel that match the computer.

FIG. 19 This is a computer for bag mounting with body and display hinged together and heat dissipation duct outlet in the hinge.

FIG. 20A This is a cross section of a computer with multi function hinge and heat dissipation duct outlet. Shown is the duct passing through the computer body to the hinge outlet.

FIG. 20B This is a magnified view of a cross section showing the heat dissipation duct leading out through the computer body hinge extension.

FIG. 21A This is a view of a bag computer with its display panel pivoted flat against the bag front.

FIG. 21B This is a view of a bag computer with its display panel pivoted perpendicular to the bag front and in the line of sight of the operator.

FIG. 21C This is a view of a bag computer with its display panel pivoted up above and parallel to the bag front for viewing from in back of the bag.

FIG. 22 This figure shows the method for holding the bag computer in the lap and viewing the display from in back of the bag.

FIG. 23 This figure shows the method for holding the computer in FIG. 22 can also be used for typing.

FIG. 24 This figure shown an operator viewing and using a bag computer held flat in his lap.

FIG. 25 This figure shows the operator prone while holding the bag computer on his stomach and viewing the display from in back of the bag.

### DETAILED DESCRIPTION OF THE INVENTION

The multi function hinge for bag computers is special for bag computers and improves their performance. As explained below, they provide functions that are not needed in computers not meant for the bag front venue.

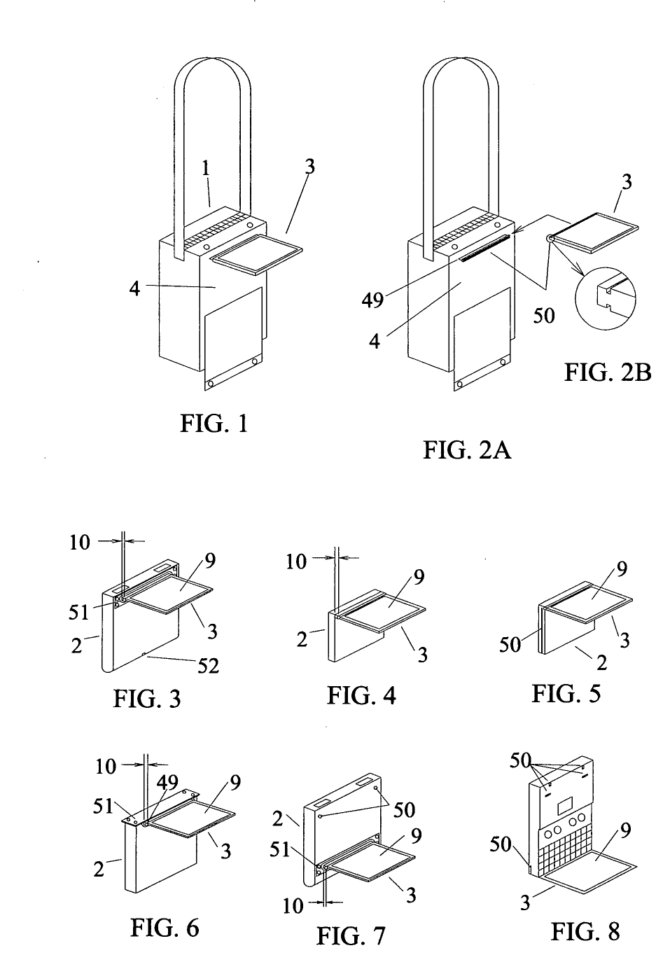

Bag computers, FIG. 1, for example, are a bag 1 and computer combination designed so that, when assembled, the computer's display panel 3 can pivot from a vertical position along the outside of the bag front wall 4 to position with the display facing and in the line of sight of the operator/wearer. Manual controls and computing unit are also included. Bag computers include an interior space for carrying general cargo.

In all cases, the display panel must pivot on the bag front and this pivoting may be accomplished with a display panel to bag front hinge which may be multi functional. Bag computers with removable displays may have components arranged is several ways. Hence, the multi function hinge may be located in a number of different bag computer component venues.

As shown in FIG. 2, the hinge 49 may be located on the bag front 4 where a removable display panel 3 attaches to it with matching attachments 50. The computing unit may be located inside the bag or in the display panel.

Alternatively, shown in FIG. 3, the hinge 49 may be located between the body 2 and display 3 panels of a computer specially adapted to mount on the inside surface, outside surface or be a part of the bag's front wall.

The body panel has a front surface nearest the display when closed, an opposite back surface, a bottom edge, top edge and two side edges. The display panel attaches with a hinge means with its display facing toward or away front the bodies front surface depending on the particular computer configuration.

Such a specialized computer, as shown in FIG. 3, may have its computer body 2 mounted inside the front bag wall with an inside mounting structure and the display panel 3 protruding out the front bag wall through an opening. Its display 9 may face out on the display panel 3 when shut. It would have a size, shape and fitting, such as physical and electrical connections 52, hinge extension 10 and/or computer to bag coupling 51, to match the bag that holds it.

As shown in FIG. 4, the computer with its display 9 facing out on the display panel 3 when shut may instead be mounted in a holster on the outside front surface of the bag with body 2 shape, attachments, hinge extension 10 and fittings to match the bag.

Alternatively, as shown in FIG. 5, a computer with its display 9 facing out on the display panel 3 when shut may be mounted on the outside of the front bag wall using body 2 attachments 50 which match a docking port on the bag's outside front.

In another venue for the multi function hinge 49 for bag computers, shown in FIG. 6, the computer with its display 9 facing out on the display panel 3 when shut may be installed through an installation opening in the bag's top wall. An inside mounting structure for the body may be on the inside of the bag's front wall. The display panel 3 has a hinge extension to allow it to pivot shut over the bag's outside front. This computer would have a size, body 2 shape and fittings, such as physical and electrical connections, hinge extension 10 and/or bag to computer coupling 51, to match the bag that holds it.

Shown in FIG. 7, the computer may have its display 9 facing inward on the display panel 3 while shut and be installed to a mounting structure on the front wall inside surface with the display panel projecting through an opening in the bag's front wall. This computer would include body 2 size and shape, fittings, such as attachments 50, hinge extension 10 and/or bag to computer coupling 51, to match the bag that holds it.

Shown in FIG. 8, the computer may have its display 9 facing inward on the display panel 3 while shut and be installed to a mounting structure on the front wall outside surface. This computer would include fittings, such as attachments 50 to match the bag that holds it.

The bag computer may be seen as a system using a collection of components which, when assembled, result in a unit with one utility. It is anticipated that there may be other means of mounting a computer to a bag's front wall to produce a bag computer's operating characteristics. The bag computer multi function hinge utility is equally applicable to bag computers produced by any of these means.

The first function of the multi function hinge for bag computers, to be used separately or in combination with other functions, is a position holdings hinge disengagement mechanism allowing a quick switch between an angular position holding display panel to a free swinging display panel. While operating a bag computer, the operator might want to have the option to have the display hinge either 1) hold its angular position so that the display can be viewed without holding the display panel, or 2) have the display panel free swinging so that the panel may fall flat against the bag front when not held. In this way, the display panel will not interfere with other tasks the operator might have in front of him. The position holding mechanism may either allow forced movement or lock the display in a position. The hinge may consist of a “half hinge” on the display panel matching and fitting to a “half hinge” on the computer/body panel or bag front. A separate axle may be employed to connect the two.

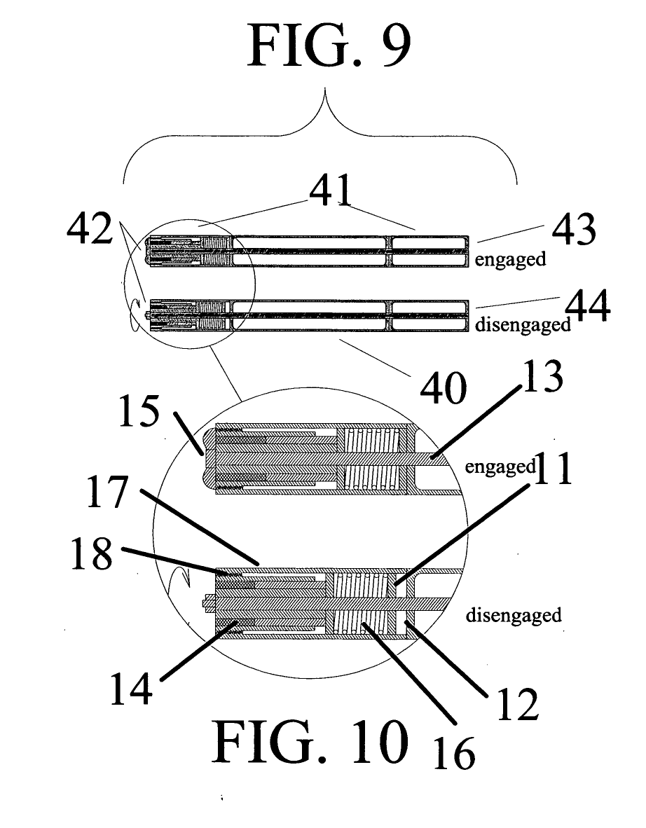

FIG. 9 shows one embodiment of a position holding hinge means with disengagement mechanism. The hinge may consist of two or more half hinges, 40 and 41, some on the display panel and others on the computer's body panel or bag front. By actuating the disengagement mechanism 42, the hinge's position holding quality may be engaged 43 or disengaged 44.

FIG. 10 shows, in magnification, that the position holding mechanism may be a movable disk surface 11 on one of the half hinges (display or body) which matches and engages a stationary disk surface 12 on the opposing half hinge to produce the friction needed to hold the hinge angle. The disk contact surfaces may have friction or ratchet/pawl surfaces. The disk surfaces may be shaped as, for example, a dome or cone or other shape to improve friction characteristics. The movable friction surface may move parallel to the axle 13 but is keyed to the half hinge housing 17 so that it cannot rotate around the axel. A spring 16 or elastic cushion may be included to maintain steady pressure even if wear occurs.

The hinge has a disengagement mechanism to allow the hinge to swing freely. The movable friction surface may be disengaged from the stationary friction surface with a disengagement screw 14, button, lever or other device capable of moving the fiction disk along the axle axis. In the pictured case, the engagement screw engages/disengages the friction surfaces by sliding the movable disk surface parallel to the axle with a twisting handle 15 on the end of the hinge.

In addition, there may be an angular resistance adjustor such as a separate threading/screw 18 to move the entire engagement/friction surface assemble in or out of the hinge housing along the axle axis to modify the amount of friction when the friction surfaces are engaged.

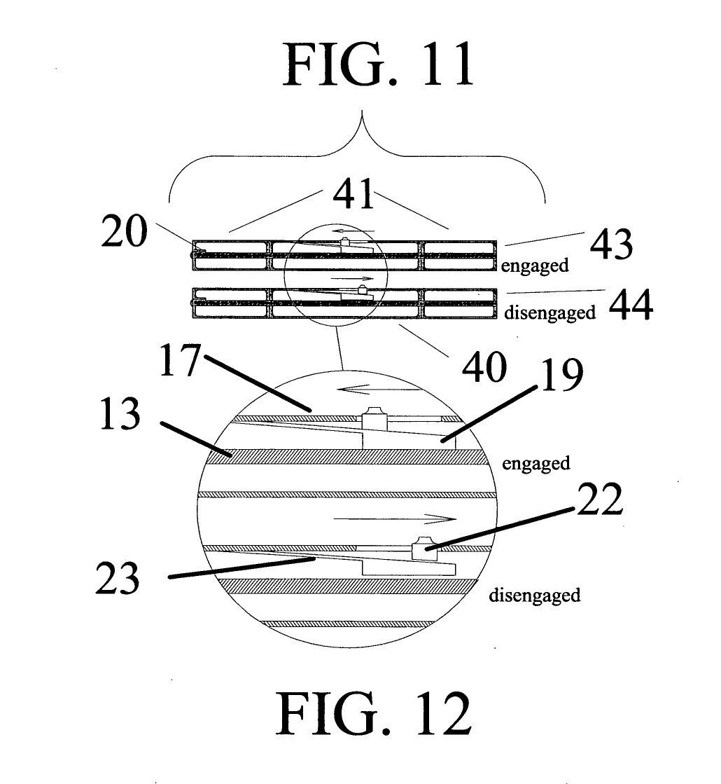

FIG. 11 shows an alternative embodiment of a position holding hinge means with disengagement mechanism. The hinge may consist of two or more half hinges, 40 and 41, some on the display panel and others on the computer/body panel or bag front. By actuating the disengagement mechanism, the hinge's position holding quality may be engages 43 or disengaged 44.

The position holding hinge may, as shown magnified in FIG. 12, consist of a brake 19 which uses a friction surface or ratchet/pawl to engage the hinge's axle 13 and acts as a brake. The axle is keyed into one half hinge (display or body) 20 so it cannot move relative to that part. The brake is located on and attached to the opposing half hinge housing 17 with guides, lever arm 23 or other holder that fixes its position relative to that housing while allowing movement for engagement.

The brake may be engaged/disengaged using a disengagement mechanism such as a sliding wedge 22, screw, cam, button or other means of applying pressure to the brake. The disengagement mechanism may be accessible from the outside of the hinge housing.

The disengagement mechanism may be adjustable so that the friction on the axle may be varied. The brake may have a spring or elastic cushion included to maintain steady pressure even if wear occurs.

Because the free swinging display may hit hard against the computer body or bag front, there may be included on the computer body or bag front a shock absorber such as a rubber cushion or other suitable absorbing material.

In another function of the multi function bag computer hinge, to be used separately or in combination with other functions, the hinge may be a venue for computer sound. If the computer is mounted inside the bag with the display protruding out through an opening to the outside front of the bag or if the hinge is part of the bag with a separate computer body mounted inside the bag, the hinge is the most reasonable place to put the computer sound device. Independent sound openings in the bag are not needed.

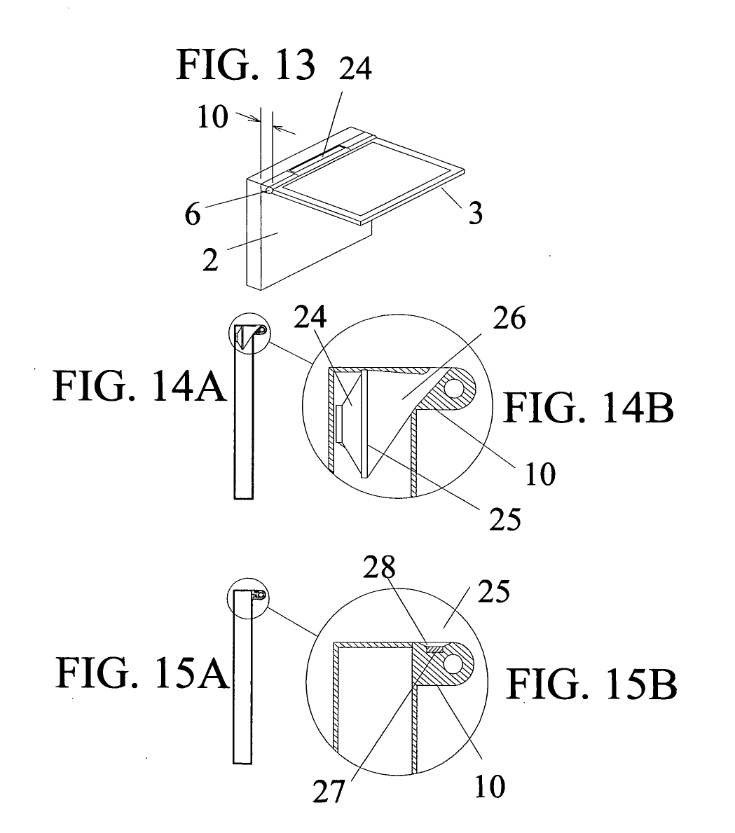

As shown in FIG. 13, if the computer is meant to mount on the inside of a bag with its display protruding out through an opening in the bag front or in a holster on the bag front, the hinge means 6 between the body 2 and display panel 3 has an extension 10 out from the body so that the display can shut with the bag material between the body and display.

In one embodiment, FIG. 14A and FIG. 14B, the speaker 24 is mounted inside the computing unit body. Extending from the audio outlet 25 of the speaker through the body and stationary half hinge portion of the hinge extension 10 and out a sound outlet in its top and facing up is a sound tunnel 26 to carry the sound. The speaker outlet may be larger than the tunnel outlet allowing a larger speaker. The tunnel outlet may be covered with a grill, sound permeable membrane or other protection. There may be one or more speakers, tunnels and outlets.

As shown in FIG. 15A and FIG. 15B, the speaker may, alternatively, be mounted directly on or embedded into the hinge extension 10 upper surface with its audio outlet 25 directed upward. The speaker driver 27 may be located in the hinge extension and attached to a membrane 28 serving the purpose of a speaker cone and speaker protection as well as directing the sound upward to the operator.

Alternatively, the speaker mounted to the hinge extension may be a flat acoustic panel attached to the upper surface. There may be more than one speaker mounted on the hinge extension.

In either of these arrangements, the speaker may extend from the hinge extension onto the top edge of the computer body as in the case where the computer is mounted in a pocket and the entire top of the computer is exposed.

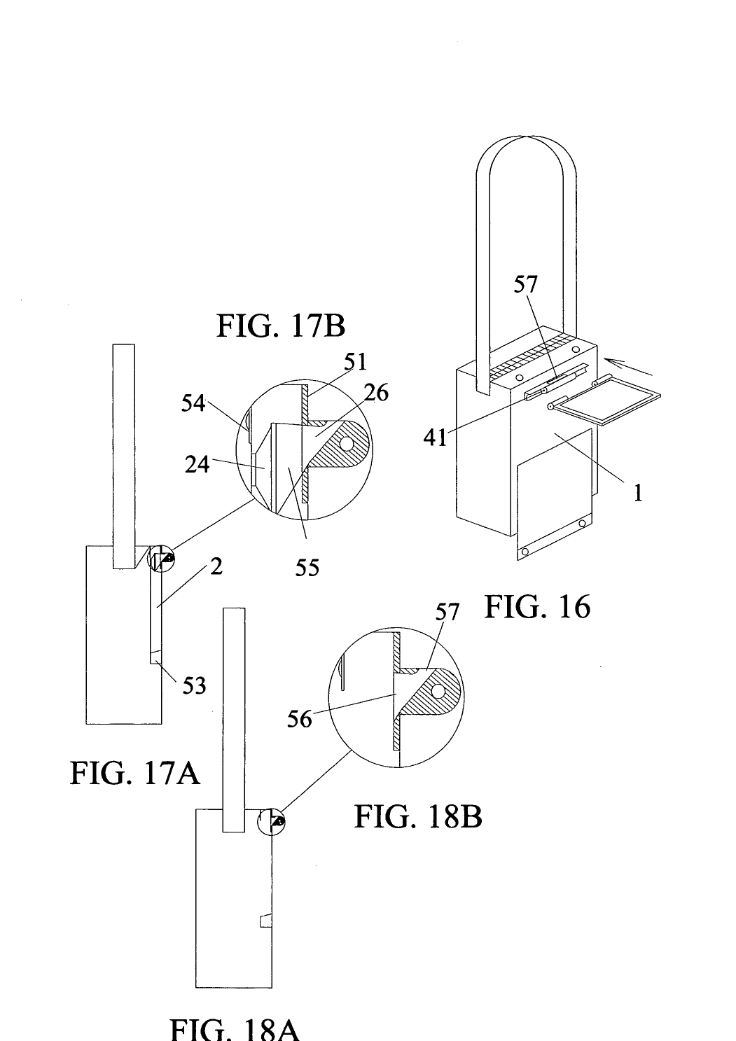

Shown in FIG. 16, if the display to bag front hinge 41 is part of the bag 1 with the computing unit in a separate body mounted inside the bag, the hinge may have a sound tunnel to carry sound from a speaker in the body to a sound outlet 57 in the top of the hinge extension where it faces up toward the operator. Shown in FIG. 17A and magnified in FIG. 17B, the inside computer 2 is mounted to the inside of the front wall with a mounting structure such as a footing 53 and flap 54, so that a sound tunnel 55 in the body leads from the speaker 24 to an outlet in the body which aligns with the bag's coupling 51 and a continuation of the sound tunnel 26 in the coupling which carrying the sound through the hinge and to the sound outlet in its top. FIG. 18A and magnified in FIG. 18B show the bag without the computer mounted. The coupling with the inside 56 and outside 57 openings can be seen.

Alternatively, a display to bag front hinge as part of the bag with a separate computer body mounted inside the bag may have the speaker mounted to the upper surface of the hinge extension, as described above.

In another function of the multi function bag computer hinge, to be used separately or in combination with other functions, the hinge may be a venue computing unit heat dissipation duct outlet.

If the computer is mounted inside the bag with the display protruding out through an opening to the outside front of the bag or if the hinge is part of the bag with a separate computer body mounted inside the bag, the hinge is the most reasonable place to put the heat dissipation duct.

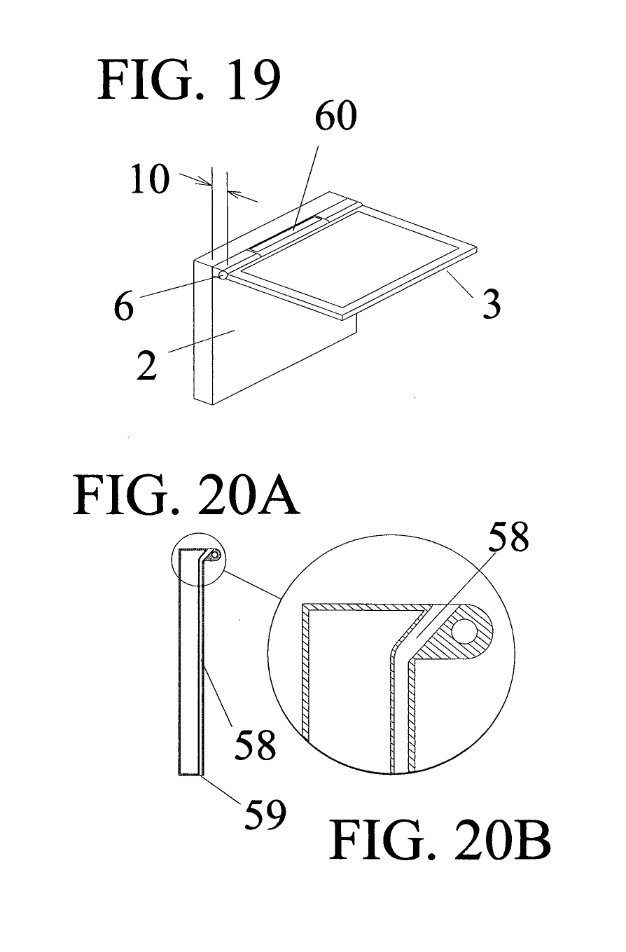

In computers with a display panel 3 and a body panel 2 hinged 6 together, shown in FIG. 19, FIG. 20A and magnified in FIG. 20B, the inside mounted computer body may have one or more heat dissipation ducts 58 to carry heat away from internal components and/or heat sinks. These ducts may have an inlet 59 near the bottom of the computer body and lead past hot electrical elements in the computing unit and through the hinge extension 10 and through a computer heat dissipation outlet 60 to the outside of the computer. The heat dissipation system may employ passive draft or may include a fan driven by the memory disk drive or other motor.

Heat dissipation ducts may be used instead with a display to bag front hinge that is part of the bag. In this case, a separate computer body is mounted on the inside the bag's front wall with a mounting structure. The heat duct outlet in the body aligns with a continuation of the heat duct in the bag's coupling which carries the heat to the computing unit heat dissipation outlet in the top of the hinge.

These heat dissipation outlets and ducts are similar to the sound tunnels described above and may be combined with the sound tunnels coming front internally mounted speakers.

In another function of the multi function bag computer hinge, to be used separately or in combination with other functions, the hinge may be a venue for an antenna.

The display to bag front hinge may act as a mounting place for one or more antennas so that the computer may communicate with other components on the bag or with external equipment without direct wiring. Antennas, such as radio frequency or infrared, may be mounted inside the hinge or on the surface of the hinge. For example, an infrared antenna may be mounted to the lower surface of the hinge and directed toward a keyboard or other input/output device mounted lower down on the bag's front surface. An infrared antenna may instead be mounted facing forward to communicate with external receivers.

In another function of the multi function bag computer hinge, to be used separately or in combination with other functions, the hinge a means and method of improving the visibility of the display by pivoting it about 180 degrees from its storage position.

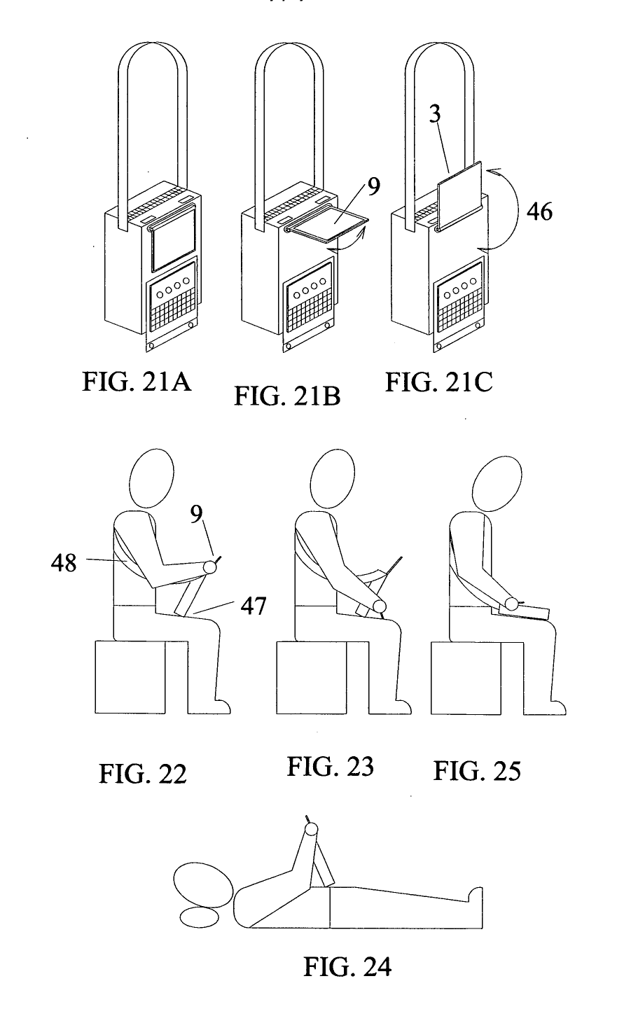

As shown in FIGS. 21A, 21B and 21C, if the display panel 3 is allowed to swing about 180 degrees 46 from the stored position, the display 9 will be facing backward toward the operator's body and viewable over the top of the bag. When the operator is sitting, FIG. 22, the bottom wall of the bag 47 may be supported by the operator's lap and the upper end of the bag may be supported by the shoulder strap 48 of the bag so that it remains in a more upright position. In this way, the display 9 is more directly in front of the operator. FIG. 23 shows that typing is possible in this position. This position may also be used when the operator is standing or prone, FIG. 24. As an option to viewing the display while the bag is resting on its back in the operator's lap, FIG. 25, this position moves the display away from the operator's body and may reduce neck strain.

Improvements to the bag's hinge include 1) positioning the hinge as near as possible to or at the corner between the front surface and top edge of the bag and computer, 2) including a hinge stop on the bag and/or computer to reinforce and hold the display panel to a maximum 180 degree position, 3) including a lock on the hinge to lock the display panel into the 180 degree position.

I claim:

1. A computer comprising:
a bag having a front wall, an opposing back wall, a bottom wall, and a plurality of side walls connecting the front wall to the back wall, and the top wall including a top opening for providing access to an interior of the bag;
a storage compartment defined by an interior space configured by connecting the front wall to the back wall;
a display panel, wherein the display panel is pivotally secured on a horizontal axis on the outside of the front wall;
a computing unit attached to the bag and electrically connected to the display panel; and
a display panel to bag front hinge wherein the hinge can switch between an angular position holding display panel to a free swinging display panel.

2. The computer of claim 1, wherein the display panel to bag front hinge includes an angular resistance adjustor to modify the amount of friction in the hinge.

3. The computer of claim 1, wherein the computing unit and/or the display panel are removably secured.

4. A computer comprising:
a bag having a front wall, an opposing back wall, a bottom wall, and a plurality of side walls connecting the front wall to the back wall, and the top wall including a top opening for providing access to an interior of the bag;
a storage compartment defined by an interior space configured by connecting the front wall to the back wall;
a display panel, wherein the display panel is pivotally secured on a horizontal axis on the outside of the front wall;
a computing unit attached to the bag and electrically connected to the display panel; and
a display panel to bag front hinge wherein the hinge has one or more sound outlets.

5. The computer of claim 4, wherein the sound outlet is the end of a tunnel carrying sound from the computer body through the hinge to the outlet.

6. The computer of claim 3, wherein the computing unit and/or the display panel are removably secured.

7. A computer comprising:
a bag having a front wall, an opposing back wall, a bottom wall, and a plurality of side walls connecting the front wall to the back wall, and the top wall including a top opening for providing access to an interior of the bag;
a storage compartment defined by an interior space configured by connecting the front wall to the back wall;
a display panel, wherein the display panel is pivotally secured on a horizontal axis on the outside of the front wall;
a computing unit attached to the bag and electrically connected to the display panel; and
a display panel to bag front hinge wherein the hinge includes one or more computing unit heat dissipation outlets leading from electrical elements in the computing unit and through the hinge.

8. The computer of claim 7, wherein the computing unit and/or the display panel are removably secured.

9. A computer comprising:
a bag having a front wall, an opposing back wall, a bottom wall, and a plurality of side walls connecting the front wall to the back wall, and the top wall including a top opening for providing access to an interior of the bag;
a storage compartment defined by an interior space configured by connecting the front wall to the back wall;
a display panel, wherein the display panel is pivotally secured on a horizontal axis on the outside of the front wall;
a computing unit attached to the bag and electrically connected to the display panel; and
a display panel to bag front hinge wherein the hinge includes one or more antennas.

10. The computer of claim 9, wherein the antenna is infrared.

11. The computer of claim 9, wherein the computing unit and/or the display panel are removably secured.

12. A computer comprising:
a bag having a front wall, an opposing back wall, a bottom wall, and a plurality of side walls connecting the front wall to the back wall, and the top wall including a top opening for providing access to an interior of the bag;
a storage compartment defined by an interior space configured by connecting the front wall to the back wall;
a display panel, wherein the display panel is pivotally secured on a horizontal axis on the outside of the front wall;
a computing unit attached to the bag and electrically connected to the display panel; and
a display panel to bag front hinge wherein the hinge can pivot about 180 degrees to be facing backward toward the operator's body and viewable over the top of the bag.

13. The computer of claim 12, wherein the computing unit and/or the display panel are removably secured.
